(19) United States
(12) Patent Application Publication
(10) Pub. No.: US 2009/0002943 A1
(43) Pub. Date: Jan. 1, 2009

(54) COOLING DEVICE FOR AN ELECTRONIC EQUIPMENT CABINET

(75) Inventors: Daniel Peron, Lannion (FR); Christian Joncourt, Lannion (FR); Daniel Crehan, Lannion (FR)

Correspondence Address: SUGHRUE MION, PLLC, 2100 PENNSYLVANIA AVENUE, N.W., SUITE 800, WASHINGTON, DC, 20037, US

(73) Assignee: Alcatel Lucent, Paris (FR)

(21) Appl. No.: 12/137,098

(22) Filed: Jun. 11, 2008

(30) Foreign Application Priority Data
Jun. 12, 2007 (FR) 0755671

(51) Int. Cl. H05K 7/20

(52) U.S. Cl. 361/694

(57) ABSTRACT

An example embodiment includes three fans (F4, F5, F6) associated with three compression chambers (respectively CH2; CH3; CH4) that are separated from one another by walls (W5, W6) capable of maintaining a difference in pressure. One of the fans (F4) causes, in the chamber (CH3) associated with said fan, a pressure greater than that caused by the other fans (F4, F6) in the other chambers (CH2, CH4), in order to create air currents (C17, . . . , C20) with a higher flow, and which are intended to cool circuit boards (B16, B17, B18) having a lower dissipation than the other boards (C12, . . . , C15, C19, . . . , C22).

The invention pertains to a cooling device for an electronic equipment cabinet, in particular cabinets that comply with ATCA (Advanced Telecom Computing Architecture) standards. These cabinets may be made up of multiple subassemblies:

A main subassembly having an open front face, and a rear face including a backplane equipped with connectors for circuit boards. This main subassembly includes upper rails and lower rails intended to accept circuit boards inserted parallel to a single vertical plane, and perpendicular to the backplane. These rails are separated by spaces that allow air to circulate. Each circuit board includes a metal strip that constitutes a vertical segment of the front face, when this board has been inserted into the subassembly. The free board slots are blocked by filler boards.

a cooling subassembly is placed above or below the main subassembly. It includes means for circulating air, and means for distributing that air into a plurality of distinct currents that each circulate in spaces that separate the boards. Two cooling subassemblies may potentially be included: one atop the main subassembly, and the other below. This cooling subassembly may be made up of a single drawer including multiple fans and means for distributing air currents, in such a way as to obtain approximately the same level of airflow in each circuit board slot.

A cooling subassembly may be designed to be split into multiple modules that may be removed separately, so that some of the fans may be changed without shutting off the other fans, and therefore without shutting off the circuit boards.

For example, the document DE 20 2004 002 008 U1 describes an electronic equipment cabinet including a main subassembly containing a group of circuit boards, and a cooling subassembly, said two subassemblies being overlaid one atop the other. The cooling subassembly includes walls that delimit a chamber. On a vertical face, this chamber includes an air intake and fans for creating overpressure in this chamber. On an upper face, it includes horizontal rails for mounting the circuit boards, separated by spaces that make it possible to circulate a plurality of distinct air currents each intended to circulate in spaces separating these boards.

Known cooling subassemblies are designed to achieve the same level of airflow at each circuit board slot, considering all the circuit boards to have the same maximum dissipation, such as 200 W for each board. In practice, the boards inserted into such a cabinet do not have the same functions, and therefore have very different dissipations. Achieving the same level of airflow at each circuit board slot is therefore not an optimal use of the cooling means. The cost of constructing a cooling subassembly is therefore not optimized. Furthermore, the amount of noise generated may be needlessly high.

The purpose of the invention is to remedy this drawback.

The subject of the invention is a cooling device for an electronic equipment cabinet including a main subassembly containing circuit boards, and a cooling subassembly, said two subassemblies being placed one atop the other, said cooling subassembly including means for creating a plurality of distinct air currents each intended to circulate in spaces separating these boards;

characterized in that the cooling subassembly includes walls delimiting at least one first chamber and one second chamber, which are independent of one another with respect to air pressure, each chamber including means for creating air currents, said first chamber and said second chamber being respectively located facing a first and a second group of circuit boards, said two groups potentially having different cooling needs;

and in that the first chamber's means for creating air currents are capable of creating overpressure or underpressure stronger than the overpressure or undepressure, respectively, than the second chamber's means for creating air currents are capable of creating.

The cooling device characterized in this manner is more optimized than known devices: the flows of the air currents created by the first chamber are different from the flows of the air currents created by the second chamber, owing to the overpressure (or underpressure) being different in both chambers. A lower overpressure (or underpressure) makes it possible to inject an optimal air current onto moderate-dissipation circuit boards, and not an excessive air current, simply by placing the boards in a manner suited for the arrangement of these two parts: the high-dissipation boards are placed facing the chamber that is producing the high-flow air currents, and the moderate-dissipation boards are placed facing the chamber that is producing the low-flow air currents. Naturally, if free slots remain facing the high-flow chamber, it is possible to place moderate-dissipation boards there.

In one preferable embodiment, the means for creating air currents include, for each chamber:

an air distribution grille;

and at least one fan.

The invention will be better understood, and other characteristics will become apparent, upon examining the description below and the figures accompanying it:

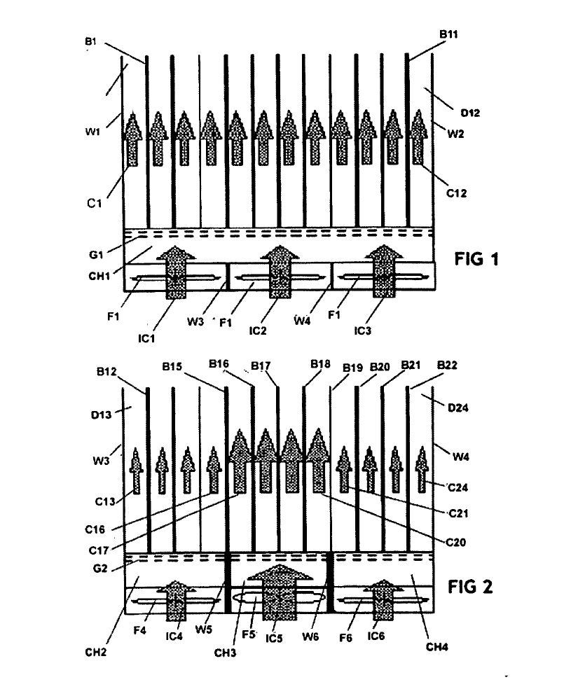

FIG. 1 represents an example embodiment of the electronic equipment cabinet including a cooling subassembly based on prior art.

FIG. 2 represents an example embodiment of the electronic equipment cabinet including a cooling subassembly of the invention.

The example embodiment based on prior art, represented in a front view in FIG. 1, comprises:

A main subassembly having a left wall W1, a right wall W2, and containing circuit boards B1, . . . , B11, inserted parallel to a single vertical plan and perpendicular to a backplane, not shown. In this example, the board slots are all occupied. These boards are separated from one another and from the walls W1 and W2 by spaces D1, . . . , D12, enabling air to circulate. Each board includes a metallic strip, which constitutes a vertical segment of the front face. The air therefore circulates in vertical conduits, each vertical conduit having an approximately parallelepiped shape delimited by a strip, the backplane, and two boards, or else by a wall and a board. The upper end of this conduit is free.

A cooling subassembly, constructed as in the prior art, is placed below the main subassembly, and it injects air vertically, from bottom to top, between the boards, in order to discharge the heat dissipated by the boards. The cooling subassembly includes a compression chamber CH1 having:
In its lower part, three identical fans F1, F2, F3, aligned along a single horizontal plane; the fans F1 and F2 being separated by a wall W3; the fans F2 and F3 being separated by a wall W4 having a length equal to the thickness of the fans; and walls W3 and W4 having a length equal to the thickness of the fans
In its upper part, a horizontal grille G1 stretches along the entire width of the cooling subassembly, with the function of creating a slight overpressure in chamber CH1 in order to approximately equalize the air currents C1, . . . , C12 which are injected into the spaces D1, . . . , D12, between the boards.
And a space formed between fans F1, F2, F3 on one side, and G1 on the other side, for creating a gap in which the air currents produced by the fans F1, F2, F3 mix together before the current resulting from the mix pass through the grille. G1.

The fans F1, F2, F3 respectively inject three identical currents IC1, IC2, IC3 that mix together within the chamber CH1 and create a uniform pressure on the grille G1. The grille G1 thereby injects the currents C1, . . . , C12 having the same airflow into each space D1, . . . , D12, respectively. This flow is calculated by considering all circuit boards to have the same maximum dissipation. For example, 200 watts for each board.

FIG. 2 depicts a front view of an example embodiment of an electronic equipment cabinet including a cooling subassembly of the invention. This cooling subassembly includes three parts: a central part obtains high-flow air currents, intended to cool high-dissipation boards, and two side parts obtain lower-flow air currents, intended to cool moderate-dissipation boards. For example, 200 watts for each board in the central part, and 100 watts for each board in the two side parts.

More precisely, this example cabinet includes:

A main subassembly having a left wall W1, a right wall W4, and containing circuit boards C12, . . . , C22, inserted parallel to a single vertical plan and perpendicular to a backplane, not shown. In this example, the board slots are all occupied. The boards B16, B17, B18 have a high dissipation, while the boards B12, . . . , B15, B19, . . . , B22 have a moderate dissipation.

These boards are separated from one another and from the walls W3 and W4 by spaces D13, . . . , D24, enabling air to circulate. Each board includes a metallic strip, which constitutes a vertical segment of the front face. The air therefore circulates in vertical conduits, each vertical conduit having an approximately parallelepiped shape delimited by a strip, the backplane, and two neighboring boards, or else by a wall and a board. The upper end of this conduit is free.

A cooling subassembly of the invention is placed below the main subassembly, and it injects air vertically, from bottom to top, between the boards, in order to discharge the heat dissipated by the boards. This cooling subassembly includes:
in its lower part, three fans F4, F5, F6, aligned along a single horizontal plane; fans F4 and F5 being separated by a wall W5; fans F5 and F6 being separated by a wall W6; and the central fan F5 being designed to inject a current IC5 having a flow significantly higher that of the currents IF4 and IF6, injected by the fans F4 and F6 respectively;
in its upper part, a horizontal grille G2 stretching along the entire width of the subassembly.

The walls W5 and W6 have a length greater than the thickness of the fans, and stretch to touch G2, thereby delimiting, along with the walls W3 and W4, three chambers CH2, CH3, CH4 whose pressure levels are independent. The function of the grille G2 is to create slight overpressures respectively in each of the three chambers CH2, CH3, CH4. The overpressure is the strongest in the chamber CH3, as the fan V5 injects into this chamber CH3 a current IC5 having a significantly greater flow (for example, twice as great) than the respective flows of currents IC4 and IC5 injected by the fans F4 and F6, respectively, into chambers CH2 and CH4.

For chamber CH2, the function of the grille G2 is to approximately equalize the respective flows of air currents C13, . . . , C16, which are injected into the spaces between a first group of four moderate-dissipation boards B12, . . . , B15. For chamber CH3, its function is to approximately equalize the flows of the air currents C17, . . . , C20 which are injected into the spaces between a group of four high-dissipation boards B16, . . . , B19. For chamber CH4, its function is to approximately equalize the flows of the air currents C21, . . . , C24 which are injected into the spaces between a group of four moderate-dissipation boards B19, . . . , B22.

The cooling subassembly thereby constructed is optimized for a group of four high-dissipation boards and a group of eight moderate-dissipation boards. However, it should be noted that boards B15 and B19 are in an intermediate situation, as they both have one face touched by a high-flow current and one face touched by a moderate-flow current. The components with the highest dissipation are generally located on a single face of the board. Consequently, one of the boards B15 and B19 may be a high-dissipation board. For example, if the components with the highest dissipation are located on the face seen at left in FIG. 2, on each board, the components with the greatest dissipation on board B18 will receive stronger cooling, owing to current C20.

Naturally, the scope of the invention is not limited to this example embodiment. It is within the purview of a person skilled in the art to adapt it to a different number of boards, and to adapt it to the power levels that are to be dissipated. It is possible to provide for a number of parts other than three. It is possible to equip each independent chamber with multiple fans. By analogy, it is also possible to construct a cooling subassembly that operates by extracting air, which is placed above the main subassembly that includes the boards.

1) A cooling device for an electronic equipment cabinet including a main subassembly containing circuit boards (B12, . . . , B22), and a cooling subassembly, said two subassemblies being placed one atop the other, said cooling subassembly including means for creating a plurality of distinct currents (C13, . . . , C24) intended to circulate, respectively, in spaces (D13, . . . , D24) separating these boards;
characterized in that the cooling subassembly includes walls (W5, W6) delimiting at least one first chamber (CH2) and one second chamber (CH3), whose air pressure levels are independent of one another, each chamber including means for creating air currents, said first chamber and said second chamber being respectively located facing a first (B12-B15) and a second group (B16-B18) of circuit boards, said two groups potentially having different cooling needs;
and in that the means (W3, F4, W5, G2) in the first chamber (CH2) to create air currents are capable of creating overpressure, or underpressure, stronger than the overpressure or underpressure, respectively, than the means (W5, F5, W6, G2) of the second chamber for creating air currents (CH3), are capable of creating.

2) A cooling device according to claim 1, characterized in that the means for creating air currents included, for each chamber (CH2; CH3):
an air distribution grille (G2);
and at least one fan (F4; F5).
